(19) United States
(12) Patent Application Publication
(10) Pub. No.: US 2006/0144558 A1
(43) Pub. Date: Jul. 6, 2006

(54) Fan-driven heat dissipating device with enhanced air blowing efficiency

(75) Inventors: Pete Chou, Taipei (TW); Frank Wang, Taipei (TW)

Correspondence Address: PEARL COHEN ZEDEK, LLP, 1500 BROADWAY 12TH FLOOR, NEW YORK, NY, 10036, US

(73) Assignee: INVENTEC CORPORATION

(21) Appl. No.: 11/025,117

(22) Filed: Dec. 30, 2004

(51) Int. Cl. H05K 7/20

(52) U.S. Cl. 165/80.3; 361/697

(57) ABSTRACT

A fan-driven heat dissipating device with enhanced air blowing efficiency is proposed, which is designed for use in conjunction with an integrated circuit device for dissipating the heat produced by the integrated circuit device during operation, and which is characterized by the provision of a secondary air outlet on the lateral side of the casing beside a primary air outlet, which allows part of the radially-flowing air stream to exit the casing laterally from the secondary air outlet, so that frictional loss due to the air flow striking against the inner wall of the casing can be reduced, allowing the fan module to provide a more enhanced air blowing efficiency than the prior art. This feature allows the fan-driven heat dissipating device of the invention to provide a more enhanced heat-dissipating efficiency than the prior art.

### FIELD OF THE INVENTION

This invention relates to heat dissipating technology, and more particularly, to a fan-driven heat dissipating device with enhanced air blowing efficiency which is designed for use in conjunction with an integrated circuit device, for dissipating the heat produced by the integrated circuit device during operation.

### BACKGROUND OF THE INVENTION

Integrated circuit devices, such as CPU (Central Processing Unit) or logic circuit chips, would normally produce large amounts of heat due to consumption of electrical power during operation. If this heat is undissipated and accumulated within the chip, it would result in burnout of electrical components in the, chip, causing the chip to fail to operate normally. One solution to this problem is to provide a heat-dissipating device, such as an electrical fan, for dissipating the heat produced by the chip during operation. For example, network servers or desktop computers are customarily mounted with one or more modularized fan units in the chassis for producing a flow of air to blow away heat in the electronic system during operation.

Patents related to fan-driven heat dissipating devices include, for example, the ROC Patent Application Number 092202625 Entitled “HEAT-DISSIPATING STRUCTURE FOR USE WITH A HEAT-DISSIPATING WINDOW ON THE CASING OF AN ELECTRONIC DEVICE”. This patented device utilizes a radial-type propeller to generate a radially-flowing stream of air (the term “radial type” herein means that when the propeller rotates, it generates a stream of air that flows radially rather than axially as most household electrical fans) and direct this air stream via a single outlet toward a thermally-conductive module coupled to the integrated circuit device for the purpose of expelling the heat accumulated on the thermally-conductive module received from the integrated circuit device.

One drawback to the aforesaid patent, however, is that it provides only one single air outlet on the casing for the air stream to exit the casing, and since the air stream is generated radially inside the casing, the majority of the air stream would strike against the inner wall of the casing before exiting from the outlet, thus resulting in a frictional loss that leads to a low air blowing efficiency and thus a low heat-dissipating efficiency.

### SUMMARY OF THE INVENTION

It is therefore an objective of this invention to provide a fan-driven heat dissipating device with a more enhanced air blowing efficiency than the prior art so as to be able to more efficiently dissipate the heat produced by the integrated circuit device during operation.

It is another objective of this invention to provide a fan-driven heat dissipating device with an enhanced air blowing efficiency that provides a more cost-effective solution to the dissipation of heat from integrated circuit devices in an electronic system.

The fan-driven heat dissipating device according to the invention is designed for use in conjunction with an integrated circuit device, such as a CPU chip or a logic circuit chip, for providing the integrated circuit device with a fan-driven heat-dissipating function to dissipate the heat produced by the integrated circuit device during operation.

The fan-driven heat dissipating device according to the invention is characterized by the provision of a secondary air outlet on the lateral side of the casing beside a primary air outlet, which allows part of the radially-flowing air stream to exit the casing laterally from the secondary air outlet, so that frictional loss due to the air flow striking against the inner wall of the casing can be reduced, thus allowing the fan module to provide a more enhanced air blowing efficiency. This feature allows the fan-driven heat dissipating device of the invention to provide a more enhanced heat-dissipating efficiency than the prior art.

### BRIEF DESCRIPTION OF DRAWINGS

The invention can be more fully understood by reading the following detailed description of the preferred embodiments, with reference made to the accompanying drawings, wherein:

FIG. 1 is a schematic diagram showing an explode perspective view of the fan-driven heat dissipating device according to the invention with an integrated circuit device;

FIG. 2 is, a schematic diagram showing a sectional view of a thermally-conductive module utilized by fan-driven heat dissipating device according to the invention;

FIG. 3 is a schematic diagram showing a top inside view of a fan module utilized by the fan-driven heat dissipating device according to the invention; and

FIG. 4 is a schematic diagram showing the assembly of the fan-driven heat dissipating device according to the invention when used in conjunction with an integrated circuit device in actual application.

### DETAILED DESCRIPTION OF PREFERRED EMBODIMENTS

The fan-driven heat dissipating device with enhanced air blowing efficiency according to the invention is disclosed in full details by way of preferred embodiments in the following with reference to the accompanying drawings.

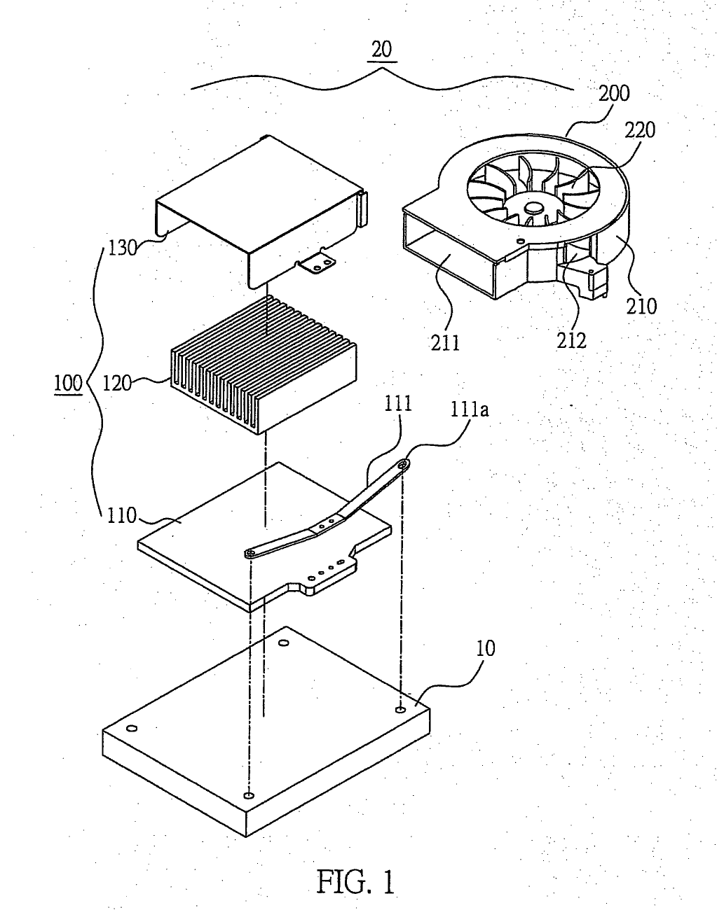

FIG. 1 is a schematic diagram showing an explode perspective view of the fan-driven heat dissipating device of the invention 20 with an integrated circuit device 10. In actual application, the fan-driven heat dissipating device of the invention 20 is used in conjunction with the integrated circuit device 10, which is for example a CPU (Central Processing Unit) chip or a logic circuit chip, for dissipating the heat produced by the integrated circuit device 10 during operation.

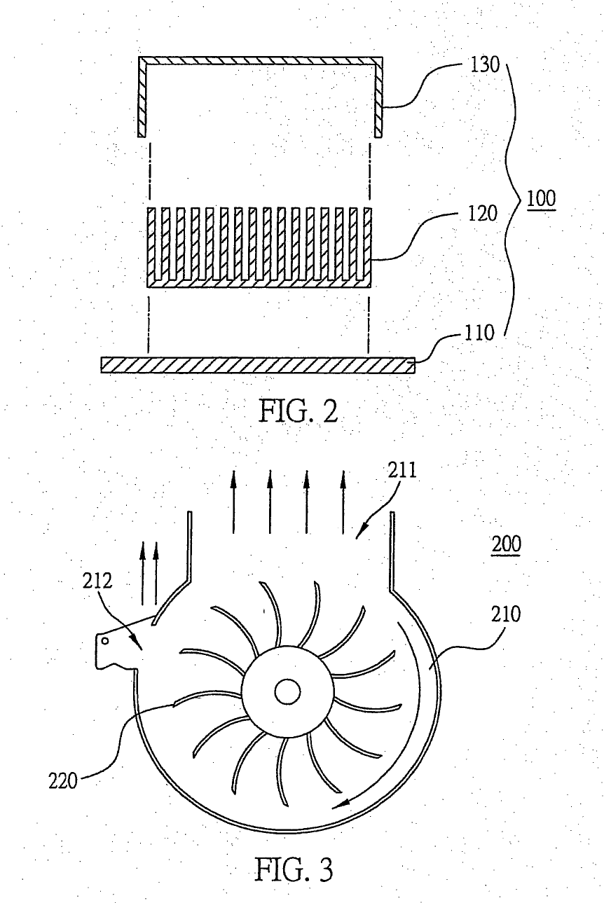

As shown in FIG. 1, the fan-driven heat dissipating device of the invention 20 comprises: (a) a thermally-conductive module 100; and (b) a fan module 200; and wherein, as also shown in FIG. 2, the thermally-conductive module 100 is composed of: (a1) a thermally-conductive plate 110; (a2) a thermally-conductive fin-like member 120; and (a3) a covering member 130.

The thermally-conductive plate 110 is made of a thermally-conductive material, such as copper, and which is provided with a chip coupling structure, such as an elastic locking member 111 whose central point is affixed to the thermally-conductive plate 110 and whose two free ends are each formed with a bolting hole 111a for use to fasten the thermally conductive plate 110 to the integrated circuit device 10 by means of bolting through the bolting hole 111a. This attachment allows the thermally-conductive plate 110 to absorb the heat produced by the integrated circuit device 10 during operation. Beside the elastic locking member 111, there exits many other various ways to fasten the thermally-conductive plate 110 to the integrated circuit device 10.

The thermally-conductive fin-like member 120 is also made of a thermally conductive material, such as copper, and which is shaped like a fin for the purpose of increasing the total surface area thereof. This thermally-conductive fin-like member 120 is securely attached to the thermally-conductive plate 110 by means of, for example, bonding with solder, for absorbing the heat produced by the integrated circuit device 10 via the thermally-conductive plate 110.

The covering member 130 is made of a rigid material, such as aluminum, and which is mounted on the thermally-conductive fin-like member 120 for providing an enclosed air flow channel through the thermally-conductive fin-like member 120.

As shown in FIG. 1 and FIG. 3, the fan module 200 is composed of a casing 210 and a radial-type propeller 220 (the term “radial type” means that when the propeller rotates, it generates a stream of air that flows radially rather than axially). The radial-type propeller 220 is mounted inside the casing 210, and the casing 210 is formed with a primary air outlet 211 and a secondary air outlet 212 (note that in the embodiment of FIG. 1, only one secondary air outlet 212 is shown, but in practice, two or more secondary air outlets can be provided), wherein the primary air outlet 211 is aimed directly at the thermally-conductive fin-like member 120 in the thermally-conductive module 100, while the secondary air outlet 212 is located on the lateral side of the casing 210 beside the primary air outlet 211 and aimed at one side of the thermally-conductive fin-like member 120. During operation when the radial-type propeller 220 rotates, it will drive the air to flow radially outwards and thus produce two exiting streams of air: one from the primary air outlet 211 and the other from the secondary air outlet 212 toward the thermally-conductive module 100. Compared, to prior art, the provision of the secondary air outlet 212 allows part of the radially-flowing air to exit laterally from the secondary air outlet 212, thus effectively reducing frictional loss from striking against the inner wall of the casing 210, allowing the fan module 200 to provide a more enhanced air blowing efficiency than the prior art.

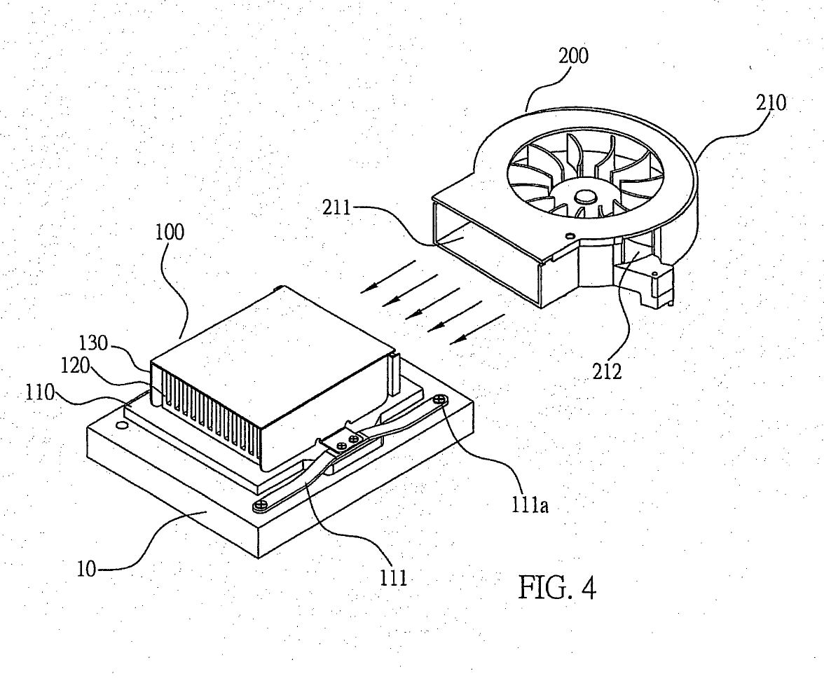

FIG. 4 is a schematic diagram showing the assembly of the fan-driven heat dissipating device of the invention 20 when used in conjunction with an integrated circuit device 10 in actual application. As shown, the thermally-conductive module 100 is coupled to the integrated circuit device 10 by means of bolting through the elastic locking member 111 so as to allow the thermally-conductive plate 110 to come in contact with the integrated circuit device 10. This attachment allows the heat produced by the integrated circuit device 10 during operation to be transmitted via the thermally-conductive plate 110 to the thermally-conductive fin-like member 120. Since the thermally-conductive fin-like member 120 has a large surface area due to its fin-like structure and the fan module 200 provides an increased amount of air flow from the primary air outlet 211 and the secondary air outlet 212, it allows the heat accumulated on the thermally-conductive fin-like member 120 to be highly efficiently blown away to the ambient atmosphere, thus more quickly dissipating the heat from the integrated circuit device 10.

Compared to prior art, since the provision of the secondary air outlet 212 on the fan module 200 allows an increased amount of air flow toward the thermally-conductive module 100, it allows the invention to provide a more enhanced air blowing efficiency and thus a more enhanced heat-dissipating efficiency than the prior art.

In conclusion, the invention provides a fan-driven heat dissipating device with enhanced air flowing efficiency for use with an integrated circuit device for dissipating the heat produced by the integrated circuit device during operation, and which is characterized by the provision of a secondary air outlet on the lateral side of the casing beside a primary air outlet, which allows part of the radially-flowing air stream to exit the casing laterally from the secondary air outlet, so that frictional loss due to the air flow striking against the inner wall of the casing can be reduced, allowing the fan module to provide a more enhanced air blowing efficiency than the prior art. This feature allows the fan-driven heat dissipating device of the invention to provide a more enhanced heat-dissipating efficiency than the prior art. The invention is therefore more advantageous to use than the prior art.

The invention has been described using exemplary preferred embodiments. However, it is to be understood that the scope of the invention is not limited to the disclosed embodiments. On the contrary, it is intended to cover various modifications and similar arrangements. The scope of the claims, therefore, should be accorded the broadest interpretation so as to encompass all such modifications and similar arrangements.

1. A fan-driven heat dissipating device for use with an integrated circuit device for dissipating the heat produced by the integrated circuit device during operation;
the fan-driven heat dissipating device comprising:.
a thermally-conductive module, which is mounted on the integrated circuit device for absorbing the heat produced by the integrated, circuit device during operation; and
a fan module, including at least a casing and a radial-type propeller mounted inside the casing, wherein the casing is formed with a primary air outlet and a secondary air outlet arranged on the lateral side of the casing beside the primary air outlet to allow a radially-flowing stream of air generated by the radial-type propeller to flow out of the casing both from the primary air outlet and the secondary air outlet toward the thermally conductive module to blow away the heat absorbed by the thermally-conductive module from the integrated circuit device.

2. The fan-driven heat dissipating device of claim 1, wherein the integrated circuit device is a CPU (Central Processing Unit) chip.

3. The fan-driven heat dissipating device of claim 1, wherein the thermally-conductive module includes:
a thermally-conductive plate, which is attached to the integrated circuit device for absorbing the heat produced by the integrated circuit device during operation;
a thermally-conductive fin-like member, which is attached to the thermally conductive plate for absorbing the heat produced by the integrated circuit device via the thermally-conductive plate; and
a covering member, which is mounted on the thermally-conductive fin-like member for providing an enclosed air flow channel through the thermally-conductive fin-like member.

4. The fan-driven heat dissipating device of claim 3, wherein the thermally-conductive module further includes:
an elastic locking member for fastening the thermally-conductive plate to the integrated circuit device by means of bolting.

5. The fan-driven heat dissipating device of claim 3, wherein the thermally-conductive plate comprises copper.

6. The fan-driven heat dissipating device of claim 3, wherein the thermally-conductive fin-like member comprises copper.

7. The fan-driven heat dissipating device of claim 3, wherein the covering member comprises aluminum.

8. The fan-driven heat dissipating device of claim 3, wherein the thermally-conductive fin-like member is securely attached to the thermally-conductive plate by means of bonding with solder.
